(19) United States
(12) Patent Application Publication
(10) Pub. No.: US 2013/0271738 A1
(43) Pub. Date: Oct. 17, 2013

(54) MOVABLE BODY APPARATUS, EXPOSURE APPARATUS, AND DEVICE MANUFACTURING METHOD

(71) Applicant: NIKON CORPORATION, Tokyo (JP)

(72) Inventor: Shigeru MORIMOTO, Kumagaya-shi (JP)

(21) Appl. No.: 13/835,786

(22) Filed: Mar. 15, 2013

Related U.S. Application Data
(60) Provisional application No. 61/640,983, filed on May 1, 2012.

(30) Foreign Application Priority Data
Apr. 13, 2012 (JP) 2012-091506

(51) Int. Cl. G03F 7/20

(52) U.S. Cl. CPC G03F 7/70758
USPC 355/30

(57) ABSTRACT

A stage device is equipped with two stages that can move along an XY plane above a stage base, a first magnet unit and a second magnet unit provided in the two stages, respectively, a planar motor which has a coil unit including a plurality of coils arranged two-dimensionally above the stage base that drives the two stages by a driving force generated by electromagnetic interaction with each of the first magnet unit and the second magnet unit. In a state where the two stages are in proximity within a predetermined distance or in contact with each other above the stage base in a Y-axis direction, a layout of magnets is decided so that no magnets structuring the first magnet unit and no magnets structuring the second magnet unit simultaneously face the same coil structuring the coil unit.

### BACKGROUND OF THE INVENTION

1. Field of the Invention

The present invention relates to movable body apparatuses, exposure apparatuses, and device manufacturing methods, and more particularly to a movable body apparatus equipped with two movable bodies driven by a planar motor, an exposure apparatus equipped with the movable body apparatus, and a device manufacturing method using the exposure apparatus.

2. Description of the Background Art

Conventionally, in a lithography process for manufacturing electron devices (microdevices) such as a semiconductor device (integrated circuit and the like), a liquid crystal display device and the like, various exposure apparatuses are used. For example, as an exposure apparatus used for manufacturing a semiconductor device, a liquid immersion exposure apparatus is known which performs exposure on a wafer via an optical system and a liquid. As this type of exposure apparatus, for example, a type of a liquid immersion exposure apparatus which is equipped with a wafer stage on which a wafer is mounted and a measurement stage on which a measurement member is provided (refer to, for example, U.S. Patent Application Publication No. 2008/0088843), and a twin wafer stage type liquid immersion exposure apparatus which is equipped with two wafer stages (refer to, for example, U.S. Patent Application Publication No. 2011/0025998) and the like are known.

In the liquid immersion exposure apparatus disclosed in U.S. Patent Application Publication No. 2008/0088843, in order to constantly hold a liquid immersion area directly below a projection optical system, delivery of the liquid immersion area is performed between the measurement stage and the wafer stage in a state where the measurement stage and the wafer stage are in contact or in proximity within a predetermined distance. Further, in the liquid immersion exposure apparatus disclosed in U.S. Patent Application Publication No. 2011/0025998, for a similar purpose, delivery of the liquid immersion area is performed between the two wafer stages in a state where the two wafer stages are in contact with each other or in proximity within a predetermined distance.

While the size of the wafer stage is increasing along with the increase in size of the wafer, as a driving source of future wafer stages, planar motor is said to be promising. However, in the case of employing a planar motor as a driving source of the wafer stage and the like, especially a moving-magnet-type planar motor in the liquid immersion exposure apparatus of the same type as in, for example, U.S. Patent Application Publication No. 2008/0088843, U.S. Patent Application Publication No. 2011/0025998 and the like, when the two stages are in proximity for the delivery of the liquid immersion area previously described, the two stages each have a magnet that faces the same coil which generates an electric field (magnetic field) that may act on the magnets of both stages (for example, electromagnetic interaction), which in turn may make driving the two stages independently and in a stable manner difficult.

### SUMMARY OF THE INVENTION

According to a first aspect of the present invention, there is provided a first movable body apparatus, comprising: a first movable body which can move along a two-dimensional plane above a stage base; a second movable body which can move along the two-dimensional plane independently from the first movable body above the stage base; and a planar motor which has a first magnet unit including a plurality of magnets provided in the first movable body, a second magnet unit including a plurality of magnets provided in the second movable body, and a coil unit including a plurality of coils arranged two-dimensionally above the stage base, and drives the first movable body by a driving force generated by an electromagnetic interaction between the first magnet unit and the coil unit and drives the second movable body by a driving force generated by an electromagnetic interaction between the second magnet unit and the coil unit, wherein a placement of the plurality of magnets in the periphery of each of the first magnet unit and the second magnet unit on the first movable body or the second movable body is decided according to a size and a placement of coils of the coil unit, so that no magnets structuring the first magnet unit and no magnets structuring the second magnet unit simultaneously face the same first direction driving coil structuring the coil unit, in a state where the first movable body and the second movable body are in a first state of being positioned within a predetermined range above the stage base and in proximity within a predetermined distance or in contact with each other in a first direction parallel to the two-dimensional plane, and also in a state where the first movable body and the second movable body are at least in a predetermined positional relation in a second direction orthogonal to the first direction within the two-dimensional plane.

According to this apparatus, the first movable body and the second movable body can be driven in a stable manner within the predetermined plane independently from each other.

According to a second aspect of the present invention, there is provided a second movable body apparatus, comprising: a first movable body which can move along a two-dimensional plane above a stage base; a second movable body which can move along the two-dimensional plane independently from the first movable body above the stage base; and a planar motor which has a first magnet unit including a plurality of magnets provided in the first movable body, a second magnet unit including a plurality of magnets provided in the second movable body, and a coil unit including a plurality of coils arranged two-dimensionally above the stage base, and drives the first movable body by a driving force generated by an electromagnetic interaction between the first magnet unit and the coil unit and the second movable body by a driving force generated by an electromagnetic interaction between the second magnet unit and the coil unit, wherein a placement of the plurality of magnets in the periphery of each of the first magnet unit and the second magnet unit on the first movable body or the second movable body is decided according to a size and a placement of coils of the coil unit, so that an electromagnetic interaction occurs between a magnetic field generated by a predetermined coil structuring the coil unit and magnets structuring the first magnet unit, and an electromagnetic interaction does not occur between the magnetic field generated by the predetermined coil and magnets structuring the second magnet unit, in a state where the first movable body and the second movable body are in a first state of being positioned within a predetermined range above the stage base and in proximity within a predetermined distance or in contact with each other in a first direction parallel to the two-dimensional plane, and also in a state where the first movable body and the second movable body are at least in a predetermined positional relation in a second direction orthogonal to the first direction within the two-dimensional plane.

According to this apparatus, the first movable body and the second movable body can be driven in a stable manner within the predetermined plane independently from each other.

According to a third aspect of the present invention, there is provided a third movable body apparatus, comprising: a first movable body which can move along a two-dimensional plane above a stage base; a second movable body which can move along the two-dimensional plane independently from the first movable body above the stage base; and a planar motor which has a first magnet unit including a plurality of magnets provided in the first movable body, a second magnet unit including a plurality of magnets provided in the second movable body, and a coil unit including a plurality of coils arranged two-dimensionally above the stage base, and drives the first movable body by a driving force generated by an electromagnetic interaction between the first magnet unit and the coil unit and the second movable body by a driving force generated by an electromagnetic interaction between the second magnet unit and the coil unit, wherein a total of a distance from an end on one side of the first movable body to an end on one side of the first magnet unit and a distance from the end on the other side of the second movable body to an end on the other side of the second magnet unit, in a first direction parallel to the two-dimensional plane, includes a length which is at least one coil length in the first direction.

According to this apparatus, the first movable body and the second movable body can be driven in a stable manner within the predetermined plane independently from each other.

According to a fourth aspect of the present invention, there is provided an exposure apparatus which exposes an object with an energy beam via an optical system and liquid, the apparatus comprising: at least one of a first movable body apparatus and a second movable body apparatus wherein the object is mounted on the first movable body or the second movable body, or on the first movable body and the second movable body; and a liquid immersion device which supplies liquid to an area directly below the optical system and forms a liquid immersion area between the optical system and the first movable body or the second movable body, or the optical system and the first movable body and the second movable body, wherein delivery of the liquid immersion area is performed between the first movable body and the second movable body when the first movable body and the second movable body are in the first state.

According to this apparatus, the gap distance between the first movable body and the second movable body can be constantly maintained, which keeps the first movable body and the second movable body from colliding, and keeps the liquid from leaking through the gap between the movable bodies.

According to a fifth aspect of the present invention, there is provided a device manufacturing method, including: exposing a sensitive object using the exposure apparatus described above; and developing the object which has been exposed.

### BRIEF DESCRIPTION OF DRAWINGS

In the accompanying drawings;

FIG. 1 is a view schematically showing a structure of an exposure apparatus related to an embodiment;

FIG. 2 is a view showing a stage device of FIG. 1;

FIG. 3 is a planar view showing an enlarged view of a measurement stage of FIG. 2;

FIG. 4 is a view used for describing a positional relation between a coil unit and a magnet unit in a state where a wafer stage and a measurement stage are in proximity or are in contact;

FIG. 5 is a view showing a bottom surface view of the wafer stage and the measurement stage in the state of FIG. 4;

FIG. 6 is a block diagram showing an input/output relation of a main controller which mainly structures a control system of the exposure apparatus related to the embodiment;

FIG. 7 is a view used for describing an operation of the exposure apparatus related to the embodiment;

FIG. 8 is a view used for describing a first modified example; and

FIG. 9 is a view used for describing a second modified example.

### DESCRIPTION OF THE EMBODIMENTS

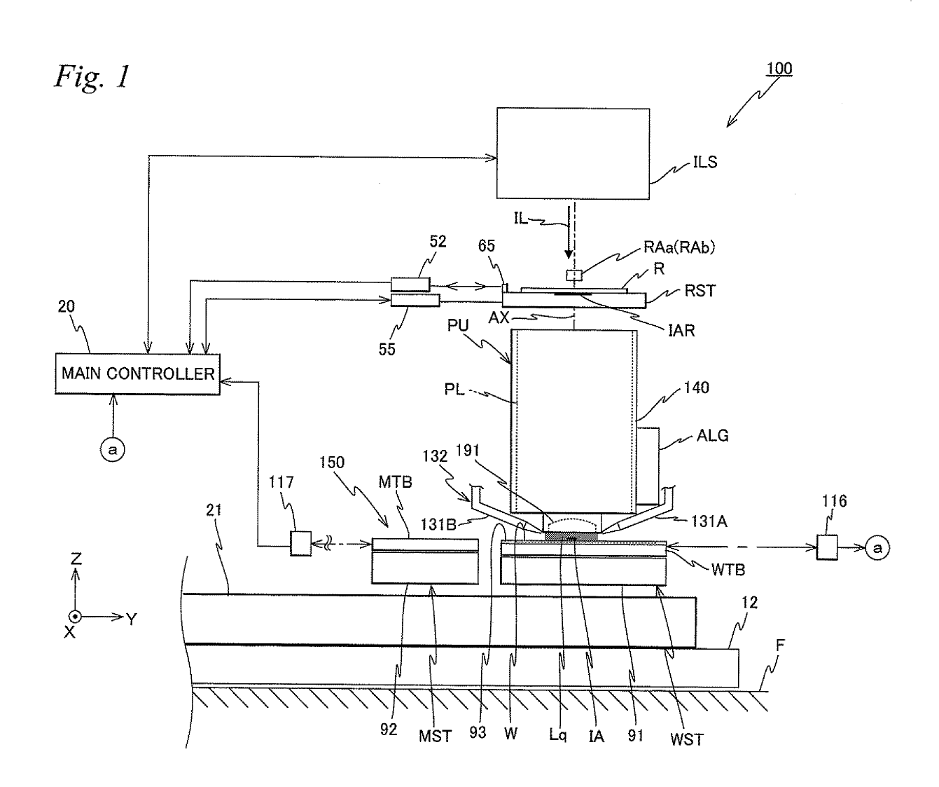

Hereinafter, an embodiment is described, based on FIGS. 1 to 7.

FIG. 1 schematically shows a structure of an exposure apparatus 100 related to the embodiment. This exposure apparatus 100 is a scanning exposure apparatus of a step-and-scan method, or a so-called scanner. As it will be described later on, in the present embodiment, a projection optical system PL is provided, and hereinafter, a direction parallel to an optical axis AX of this projection optical system PL will be described as a Z-axis direction, a direction in which a reticle and a wafer are relatively scanned within a plane orthogonal to the Z-axis direction will be described as a Y-axis direction, a direction orthogonal to the Z-axis and the Y-axis will be described as an X-axis direction, and rotation (tilt) directions around the X-axis, the Y-axis, and the Z-axis will be described as θx, θy, and θz directions, respectively.

Exposure apparatus 100 is equipped with an illumination system ILS, a reticle stage RST which moves in a predetermined scanning direction (in this case, the Y-axis direction which is the lateral direction within the page surface of FIG. 1) holding a reticle R illuminated by an illumination light for exposure (hereinafter, shortly referred to as illumination light) IL from illumination system ILS, a projection unit PU including projection optical system PL which projects illumination light IL emitted from reticle R on a wafer W, a stage device 150 including a wafer stage WST on which wafer W is mounted and a measurement stage MST used for measurement for performing exposure, a control system for these parts and the like.

As disclosed in, for example, U.S. Patent Application Publication No. 2003/0025890 and the like, illumination system ILS includes a light source, and an illumination optical system which has an illuminance equalizing optical system including an optical integrator and the like and a reticle blind and the like (none of which are shown). Illumination system ILS illuminates a slit-shaped illumination area IAR on reticle R set (limited) by the reticle blind (also called a masking system) with illumination light (exposure light) IL at an illuminance almost uniform. Here, as illumination light IL, as an example, an ArF excimer laser beam (wavelength 193 nm) is used.

On reticle stage RST, reticle R on which a circuit pattern and the like is formed on its pattern surface (a lower surface in FIG. 1) is fixed, for example, by vacuum chucking. Reticle stage RST can be finely driven within an XY plane and can also be driven in a predetermined scanning direction (in this case, the Y-axis direction which is the lateral direction within the page surface of FIG. 1) at a designated scanning velocity, for example, by a reticle stage driving system 55 including a linear motor and the like.

Position information (including rotation information in the θz direction) within the XY plane of reticle stage RST is constantly detected, for example, at a resolution of around 0.25 nm, by a reticle laser interferometer (hereinafter referred to as a “reticle interferometer”) 52, via a movable mirror 65 (a Y movable mirror (or a retroreflector) which has a reflection surface orthogonal to the Y-axis direction and an X movable mirror which has a reflection surface orthogonal to the X-axis direction are actually provided). Measurement values of reticle interferometer 52 are sent to a main controller 20, and main controller 20 controls the position (and velocity) in the X-axis direction, the Y-axis direction and the θz direction (rotation direction around the Z-axis) of reticle stage RST via reticle stage driving system 55, based on the measurement values of reticle interferometer 52.

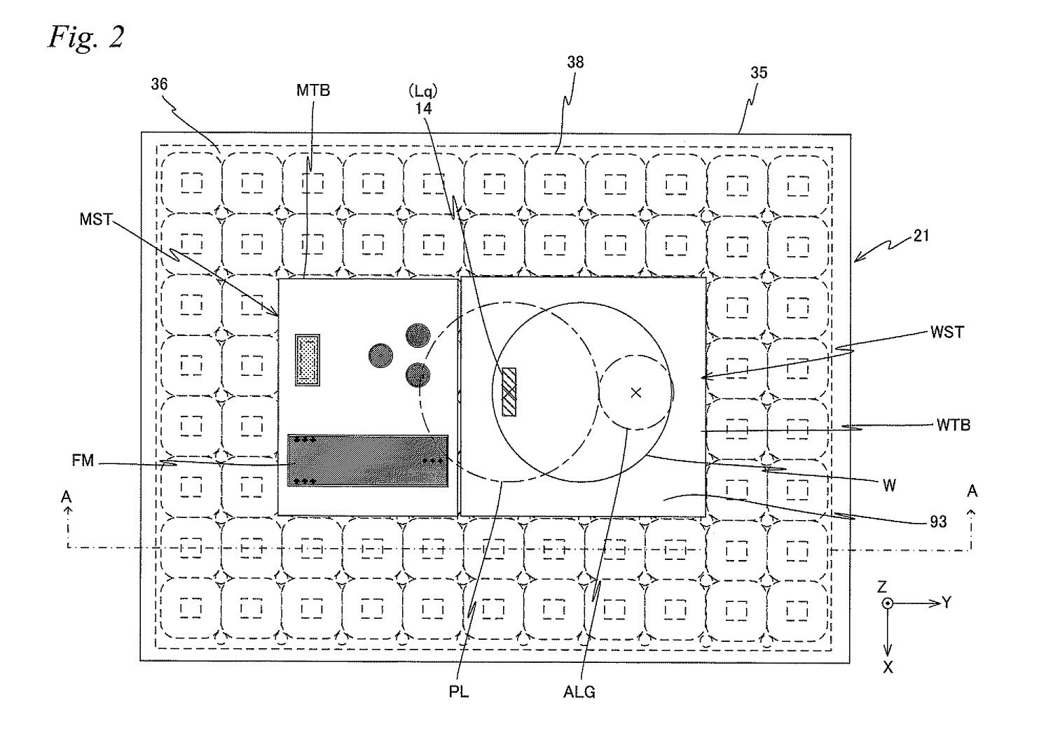

Above reticle R, a pair of reticle alignment detection systems RAa and RAb, consisting of a TTR (Through The Reticle) alignment system which uses light of the exposure wavelength to simultaneously observe a pair of reticle alignment marks on reticle R and a pair of fiducial marks (hereinafter called “a first fiducial mark”) on a fiducial mark plate FM (refer to FIG. 2 and the like) provided on measurement stage MST corresponding to the pair of reticle alignment marks via projection optical system PL, is provided set apart by a predetermined distance in the X-axis direction. As reticle alignment detection systems RAa and RAb, a system having a structure similar to the one disclosed in, for example, U.S. Pat. No. 5,646,413 and the like is used.

Projection unit PU is placed below reticle stage RST in FIG. 1. Projection unit PU includes a lens barrel 140, and projection optical system PL consisting of a plurality of optical elements held at a predetermined positional relation within lens barrel 140. As projection optical system PL, for example, a dioptric system consisting of a plurality of lenses (lens elements) that have a common optical axis AX in the Z-axis direction is used. Projection optical system PL, for example, is telecentric on both sides, and has a predetermined projection magnification (e.g., ¼ times, ⅕ times or ⅛ times). Therefore, when illumination area IAR on reticle R is illuminated by illumination light IL from illumination system ILS, by illumination light IL passing through reticle R placed so that a first plane (object plane) of projection optical system PL and the pattern surface are substantially coincident, a reduced image of the circuit pattern (a reduced image of a part of the circuit pattern) within illumination area IAR of reticle R is formed via projection optical system PL (projection unit PU), in an area (hereinafter, also called an exposure area) IA which is conjugate to illumination area IAR on wafer W which is placed on a second surface plane (an image plane) side of projection optical system PL and whose surface is coated with a resist (sensitive agent). And, by synchronously driving reticle stage RST and wafer stage WST, reticle R is relatively moved in the scanning direction (the Y-axis direction) with respect to illumination area IAR (illumination light IL), while wafer W is relatively moved in the scanning direction (Y-axis direction) with respect to exposure area IA (illumination light IL9, and scanning exposure of a shot area (divided area) on wafer W is performed, transferring the pattern of reticle R on the shot area. That is, in the present embodiment, the pattern of reticle R is generated on wafer W by illumination system ILS and projection optical system PL, and the pattern is formed on wafer W by exposing a sensitive layer (resist layer) on wafer W with illumination light IL.

Incidentally, in exposure apparatus 100 related to the present embodiment, because exposure is performed applying a liquid immersion method, an opening on the reticle side becomes larger with the substantial increase of numerical aperture NA. Therefore, in a dioptric system structured only of lenses, it becomes difficult to satisfy the Petzval condition, which tends to lead to an increase in size of the projection optical system. In order to avoid such an increase in size of the projection optical system, a reflection/refraction system (a catodioptric system) which includes a mirror and a lens can be used.

Further, in exposure apparatus 100 related to the present embodiment, in the vicinity of a lens (hereinafter also referred to as a “tip lens”) 191 which is a terminal optical element closest to the image plane side (wafer W side) that structures projection optical system PL, a liquid supply nozzle 131A and a liquid recovery nozzle 131B that structure a part of a liquid immersion device 132 are provided.

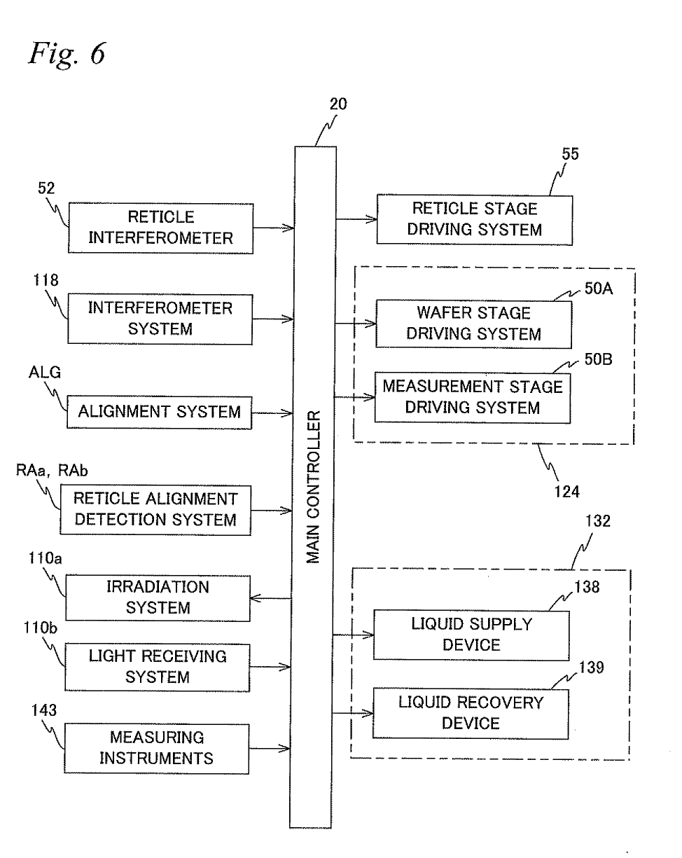

To liquid supply nozzle 131A, a liquid supply device 138 (not shown in FIG. 1, refer to FIG. 6) is connected via a supply pipe not shown, and to liquid recovery nozzle 131B, a liquid recovery device 139 (not shown in FIG. 1, refer to FIG. 6) is connected via a recovery pipe not shown.

In the present embodiment, a liquid Lq for liquid immersion (refer to FIG. 1) is to be made using pure water that transmits the ArF excimer laser beam (light with a wavelength of 193 nm). Pure water can be obtained in large quantities at a semiconductor manufacturing plane and the like without difficulty, and it also has an advantage of having little adverse effect on the resist on wafer W and to the optical lenses and the like. Refractive index n of pure water with respect to the ArF excimer laser beam is around 1.44. In such pure water, the wavelength of illumination light IL is shortened to 193 nm×1/n=around 134 nm.

Liquid immersion device 132 including liquid supply nozzle 131A and liquid recovery nozzle 131B is controlled by main controller 20 (refer to FIG. 6). Main controller 20 supplies liquid Lq to a space between tip lens 191 and wafer W via liquid supply nozzle 131A, and also recovers liquid Lq from the space between tip lens 191 and wafer W via liquid recovery nozzle 131B. On this operation, main controller 20 performs control so that the quantity of liquid Lq supplied to the space between tip lens 191 and wafer W from liquid supply nozzle 131A constantly equals the quantity of liquid Lq recovered from the space via liquid recovery nozzle 131B. Accordingly, a constant quantity of liquid Lq is held in the space between tip lens 191 and wafer W (refer to FIG. 1), and by this constant quantity of liquid, a liquid immersion area 14 is formed (e.g., refer to FIG. 2). In the case, liquid Lq held in the space between tip lens 191 and wafer W is constantly replaced.

Incidentally, it is possible to fill liquid Lq in a space between measurement table MTB and tip lens 191 similarly to the description above, or, in other words, to form a liquid immersion area, also in the case when measurement stage MST is positioned below projection unit PU.

On the +Y side of projection unit PU, as is shown in FIG. 1, an off-axis alignment system (hereinafter shortly referred to as an “alignment system”) ALG is provided which optically detects marks subject to detection such as alignment marks and the like on wafer W. Incidentally, as alignment system ALG, although sensors of various kinds of methods can be used, in the present embodiment, a sensor of an image processing method is used. Incidentally, sensors of the image processing method are disclosed in, for example, U.S. Pat. No. 5,493,403 and the like. Imaging signals from alignment system ALG are supplied to main controller 20 (refer to FIG. 6).

As shown in FIGS. 1 and 2, stage device 150 is equipped with a base board 12, a stage base 21 placed on base board 12, wafer stage WST and measurement stage MST placed above stage base 21, an interferometer system 118 (refer to FIG. 6) which measures the position of the two stages WST and MST described above, and a stage driving system 124 (refer to FIG. 6) for driving the two stages WST and MST described above.

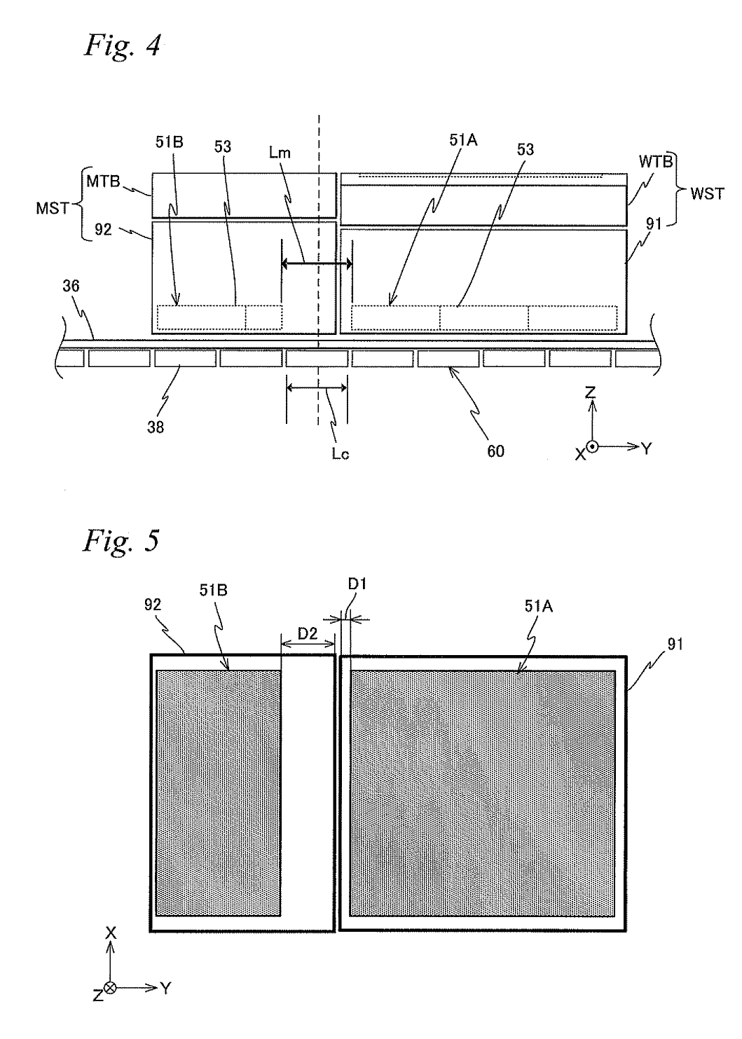

Base board 12 is supported substantially horizontal (parallel to the XY plane) on a floor surface F via a vibration isolation mechanism (not shown). Stage base 21 is supported on base board 12 via air bearings (not shown). In the upper part of stage base 21, a stator 60 (refer to FIG. 4) which will be described later on is housed. In the present embodiment, stage base 21 functions as a counter mass when driving wafer stage WST and when driving measurement stage MST, as it will be described later on. Accordingly, a trim motor for driving stage base 21 so that the moving amount of stage base 21 from a reference position falls within a predetermined range can be provided between stage base 21 and base board 12.

Wafer stage WST and measurement stage MST are each driven independent from each other by stage driving system 124. Position information of wafer stage WST and measurement stage MST in directions of six degrees of freedom (in each of the X-axis, the Y-axis, the Z-axis, the θx, the θy, and the θz directions) is detected by interferometer system 118. Incidentally, in FIG. 1, only a Y-axis interferometer 116 for measuring the position of wafer stage WST in the Y-axis direction and a Y-axis interferometer 117 for measuring the position of measurement stage MST in the Y-axis direction are shown for the sake of simplicity of the description. Measurement values of interferometer system 118 are sent to main controller 20, and main controller 20 controls the position (and velocity) of wafer stage WST and measurement stage MST via stage driving system 124, based on the measurement values of interferometer system 118. Incidentally, stage driving system 124 will be described further later on.

As shown in FIG. 1, wafer stage WST is equipped with a wafer stage main section 91, and wafer table W′E′B fixed on wafer stage main section 91. In the present embodiment, as shown in FIG. 4, a planar motor consisting of stator 60 housed in the upper part of stage base 21 and a magnet unit 51A fixed to a bottom portion (a side on a surface facing the base) of wafer stage main section 91 is used as a wafer stage driving system 50A (refer to FIG. 6).

On wafer table WTB, a wafer holder (not shown) is provided which holds wafer W by vacuum suction and the like. This wafer holder is equipped with a plate shaped main section, and a plate 93 fixed to the upper surface of the main section that has a large circular opening formed in the center which is around 0.1 to 2 mm larger in diameter than the diameter of wafer W (refer to FIGS. 1 and 2). At an area in the main section within the circular opening of plate 93, a large number of pins are placed, and by the large number of pins, wafer W is vacuum suctioned in a supported state. In this case, in the state where wafer W is vacuum suctioned, the wafer W surface and the surface of plate 93 substantially become the same height. The surface of all of the surfaces of plate 93 is coated with a liquid repellent material (water repellent material) a fluorine-based resin material, an acrylic-based resin material or the like, and a liquid repellent film is formed. Further, on the surface of wafer W, a resist (sensitive material) is coated, and the resist which is coated forms a resist film. In the case, the resist film is preferably a resist film which is liquid repellent to liquid Lq used for liquid immersion. Further, a top coat film (layer) can be formed on the surface of wafer W so as to cover the resist film. As the top coat film, it is desirable to use a film which is liquid repellent to liquid Lq used for liquid immersion.

Incidentally, a wafer stage can also be used which is equipped with a wafer stage main section that is movable in directions of three degrees of freedom within the XY plane, and a wafer table mounted on wafer stage main section via a Z-leveling mechanism not shown (including an actuator such as, for example, a voice coil motor and the like) that is finely movable in the Z-axis direction, the θx direction and the θy direction with respect to the wafer stage main section.

As shown in FIG. 1, measurement stage MST is equipped with a measurement stage main section 92, and measurement table MTB fixed onto measurement stage main section 92. In the present embodiment, as shown in FIG. 4, a planar motor consisting of stator 60 and a magnet unit 51B fixed to a bottom portion (a side on a surface facing the base) of measurement stage main section 92 is used as a measurement stage driving system 50B (refer to FIG. 6).

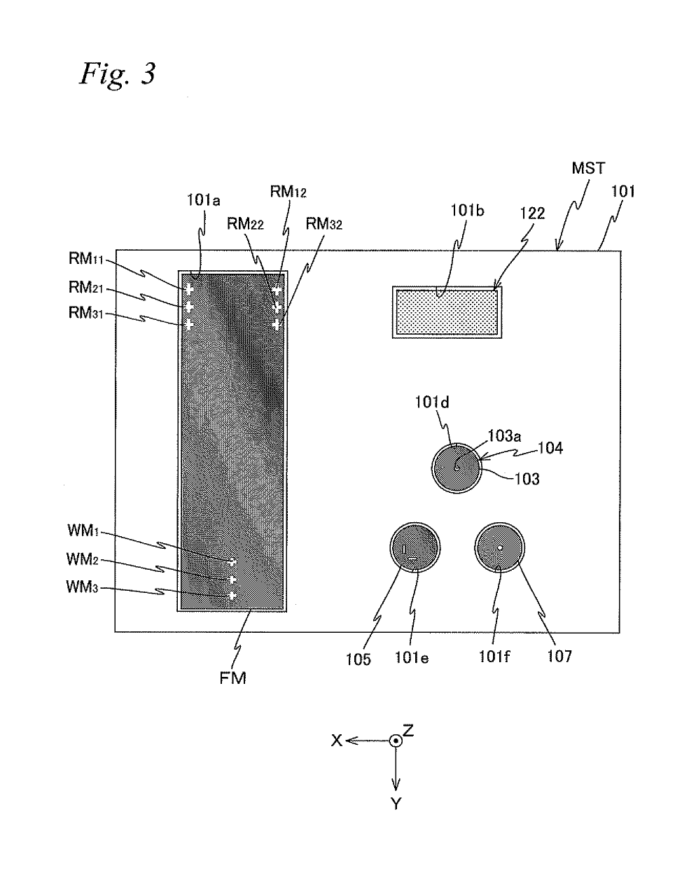

Measurement table MTB includes a hollow rectangular solid shaped housing whose upper surface is open, and a plate member 101 (refer to FIG. 3) having a predetermined thickness formed of a material having liquid repellency such as, for example, polytetrafluoroethylene (Teflon (registered trademark)) that blocks the upper surface of the housing, and has a rectangular solid shaped appearance whose dimension in the height direction is much smaller than the dimension in the width direction and in the depth direction.

As shown in FIG. 3, in plate member 101, an opening 101a which is a rectangle whose longitudinal direction is in the Y-axis direction, an opening 101b which is a rectangle that has substantially the same dimension in the X-axis direction as opening 101a with the X-axis direction serving as the longitudinal direction, and three circular openings 101d, 101e, and 101f are formed.

On the inner side of opening 101b of plate member 101 and inside the housing below opening 101b (measurement table MTB), an illuminance monitor (irradiation amount monitor) 122 is placed. The upper surface of illuminance monitor 122 is coated with a liquid repellent material (water repellent material) such as a fluorine-based resin material or an acrylic-based resin material, and by this coating, a liquid repellent film is formed. In the present embodiment, the upper surface of this liquid repellent film is set substantially in plane (flush) with the upper surface of plate member 101.

Illuminance monitor 122 in the present embodiment has a structure similar to the illuminance monitor (irradiation amount monitor) whose details are disclosed in, for example, U.S. Pat. No. 5,721,608 and the like, and measures the illuminance of illumination light IL on the image plane of projection optical system PL via liquid Lq.

Inside opening 101a of plate member 101, as shown in FIG. 3, fiducial mark plate FM which is a rectangle in a planar view is placed. The upper surface of fiducial mark plate FM is set substantially to the same height as (flush with) the surface of plate member 101. On the surface of fiducial mark plate FM, three pairs of a first fiducial mark RM₁₁ to RM₃₂ which can be simultaneously measured per pair by the pair of reticle alignment detection systems RAa and RAb previously described, and three second fiducial marks WM₁ to WM₃ which are detected by alignment system ALG are formed in a predetermined positional relation. These fiducial marks are each formed of an opening pattern formed by performing patterning in the predetermined positional relation described above on a chromium layer formed substantially on the entire surface of a member structuring fiducial mark plate FM (for example, ultra low expansion glass-ceramics, such as, e.g., CLEARCERAM (registered trademark)). Incidentally, each fiducial mark can be formed of a pattern (remaining pattern) formed by aluminum and the like.

In the present embodiment, as disclosed in, for example, U.S. Pat. No. 5,243,195 and the like, the placement of each fiducial mark described above is decided so that the first fiducial marks RMⱼ₁, RMⱼ₂ (j=1 to 3) described above can be simultaneously measured by the pair of reticle alignment detection systems RAa and RAb previously described via liquid Lq, and also simultaneously with the measurement of the first fiducial marks RMⱼ₁, RMⱼ₂, the second fiducial mark WMⱼ can be measured by alignment system ALG without going through liquid Lq. On the upper surface of fiducial mark plate FM, although it is not shown, a liquid repellent film, which is made of a liquid repellent material such as the fluorine-based resin material, the acrylic-based resin material or the like previously described, is formed on the upper part of the chromium layer previously described.

On the inner side of opening 101d of plate member 101 and inside the housing below opening 101d, illuminance irregularity measuring instrument 104 which has a pattern plate 103 that is circular in a planar view is placed.

Illuminance irregularity measuring instrument 104 has pattern plate 103 described above, and a sensor consisting of a photodetection element which is not shown (such as a silicon photodiode or a photo multiplier tube previously described) placed below the pattern plate. Pattern plate 103 is made of quartz glass and the like, and has a light-shielding film such as chromium formed on its surface, and in the center of the light-shielding film, a pinhole 103a is formed as a light transmitting section. And, on the light-shielding film, a liquid repellent film made of a liquid repellent material such as the fluorine-based resin material, the acrylic-based resin material or the like previously described is formed.

Illuminance irregularity measuring instrument 104 has a structure similar to the illuminance irregularity measuring instrument disclosed in, for example, U.S. Pat. No. 4,465,368, and measures the illuminance irregularity of illumination light IL on the image plane of projection optical system PL via liquid Lq.

Inside opening 101e of plate member 101, a slit plate 105 which is circular in a planar view is placed in a state so that its surface is substantially in plane (flush) with the plate member 101 surface. Slit plate 105 has a quartz glass and a light-shielding film such as chromium formed on the surface of the quartz glass, and slit patterns are formed extending in the X-axis direction and in the Y-axis direction at predetermined places on the light-shielding film as a light transmitting section. And, on the light-shielding film, a liquid repellent film made of a liquid repellent material such as the fluorine-based resin material, the acrylic-based resin material or the like previously described is formed. This slit plate 105 structures a part of an aerial image measuring instrument which measures light intensity of an aerial image (projection image) of a pattern projected by projection optical system PL. In the present embodiment, inside measurement table MTB (housing) below this slit plate 105, a light receiving system is provided which receives illumination light IL via the slit pattern which is irradiated on plate member 101 via projection optical system PL and liquid Lq, and by this arrangement, an aerial image measuring instrument similar to the one disclosed in, for example, U.S. Patent Application Publication No. 2002/0041377 and the like, is structured.

Inside opening 101f of plate member 101, a pattern plate 107 for wavefront aberration measurement which is circular in a planar view is placed in a state so that its surface is substantially in plane (flush) with the plate member 101 surface. This pattern plate 107 for wavefront aberration measurement has a quartz glass, and a light-shielding film such as chromium formed on the surface of the quartz glass, and a circular opening is formed in the center of the light-shielding film. And, on the light-shielding film, a liquid repellent film made of a liquid repellent material such as the fluorine-based resin material, the acrylic-based resin material or the like previously described is formed. Inside measurement table MTB (housing) below this pattern plate 107 for wavefront aberration measurement, a light receiving system including, for example, a microlens array, is provided which receives illumination light IL via projection optical system PL and liquid Lq, and by this arrangement, a wavefront aberration measuring instrument disclosed in, for example, European Patent No. 1,079,223 and the like is structured.

Incidentally, from the viewpoint of restraining thermal influence, for example, only one portion such as the optical system may be mounted on measurement stage MST in the aerial image measuring instrument or the wavefront aberration measuring instrument described above.

Furthermore, in exposure apparatus 100 of the present embodiment, although it is not shown in FIG. 1, a multi-point focal point detection system of an oblique incidence method similar to the one disclosed in, for example, U.S. Pat. No. 5,448,332 and the like which includes an irradiation system 110a and a light receiving system 110b (refer to FIG. 6) is provided.

In the present embodiment, as is shown in FIG. 4 which is a sectional view of line A-A in FIG. 2, in the bottom section of wafer stage main section 91, a plurality of permanent magnets (hereinafter shortly referred to as magnets) 53 are placed in the shape of a matrix, and these magnets 53 structure magnet unit 51A. Incidentally, while FIG. 4 is a figure when viewed from the X-axis direction, the magnets are actually placed on the XY plane in the shape of a matrix. As the plurality of magnets 53, N-pole magnets whose side is a N-pole and −Z side is a S-pole and S-pole magnets having an opposite polarity are placed alternately by a predetermined distance within the XY plane, and in between the N magnets and the S magnets, magnets are placed which are magnetized in the X-axis direction and in the Y-axis direction so that magnetic poles on the side facing the N-pole magnet are N and magnetic poles on the side facing the S-pole magnet are S, and by this arrangement, magnet unit 51A is structured. Further, in the bottom section of measurement stage main section 92, the plurality of magnets 53 are placed similarly to magnet unit 51A, and by such plurality of magnets, magnet unit 51B is structured. Incidentally, FIG. 4 is a view used to explain a positional relation between coils 38 of coil unit 60 and magnet units 51A and 51B, and in FIG. 4, the placement of the magnets of magnet units 51A and 51B is simplified and is different from the actual placement. The same can be said for the placement of coils 38 of coil unit 60.

Stage base 21, as shown in FIG. 2, is equipped with a hollow main section 35 whose upper surface is open, and a ceramic plate 36 (refer to FIG. 4) which blocks the opening section of main section 35.

In an inner space of stage base 21 formed by main section 35 and ceramic plate 36, a large number of armature coils (hereinafter shortly referred to as coils) 38 are placed in an XY two-dimensional direction, in the shape of a matrix (refer to FIG. 2). By these coils 38, a coil unit is structured which is stator 60 of a magnetic levitation type planar motor employing a moving magnet type electromagnetic driving method (hereinafter also appropriately referred to as coil unit 60) that structure each of wafer stage driving system 50A and measurement stage driving system 50B (hereinafter appropriately described as planar motors 50A and 50B). As each of the large number of coils 38, as shown in FIG. 2, a square shaped coil is used. The magnitude and direction of the electric current supplied to each of the large number of coils 38 structuring stator 60 are controlled by main controller 20 (refer to FIG. 6). Further, while the plurality of magnets (N-pole magnets and S-pole magnets) placed in the shape of a matrix are alternately placed in a predetermined distance as is previously described, the predetermined distance (magnetic pole pitch), and the size of the plurality of coils and the distance between adjacent coils are to be set in advance in a predetermined relation as specification values of the motor (planar motor). Furthermore, in the present embodiment, in a part of armature coils 38, the electric current for X thrust and the electric current for Z thrust are supplied in a superimposing manner as disclosed in, for example, U.S. Pat. No. 6,304,320, and armature coils 38 whose electric current is supplied in such a manner perform electromagnetic interaction with a part of magnets 53 that structure each of magnet units 51A and 51B so as to generate a driving force (thrust) in the X-axis direction and in the Z-axis direction. Further, in the present embodiment, in a part of coils 38, the electric current for Y thrust and the electric current for Z thrust are supplied in a superimposing manner, and coils 38 whose electric current is supplied in such a manner perform electromagnetic interaction with a part of magnets that structure each of magnet units 51A and 51B so as to generate a driving force (thrust) in the Y-axis direction and in the Z-axis direction. That is, in the present embodiment, by planar motor 50A, wafer stage WST can be driven in directions of six degrees of freedom (in each of the X-axis, the Y-axis, the Z-axis, the θx, the θy, and the θz directions). In this case, by planar motor 50A, wafer stage WST is driven in long strokes in the X-axis direction and the Y-axis direction, and is driven finely in the remaining directions of four degrees of freedom. Further, by planar motor 50B, measurement stage MST can be driven in directions of six degrees of freedom similarly to wafer stage WST. In the present embodiment, planar motor 50A structuring wafer stage driving system and planar motor 50B structuring measurement stage driving system structure stage driving system 124 (refer to FIG. 5).

FIG. 5 shows a bottom surface view of wafer stage WST and measurement stage MST. As shown in FIG. 5, in the bottom section of wafer stage main section 91 of wafer stage WST, magnet unit 51A is placed covering almost the entire surface. Meanwhile, in the bottom section of measurement stage main section 92 of measurement stage MST, magnet unit 51B is placed in a remaining area which is an area excluding the edge on the +Y side. In this case, the distance between magnet unit 51A and magnet unit 51B is indicated as Lm, as shown in FIG. 4, in a state where wafer stage WST and measurement stage MST are in proximity with each other by a predetermined distance, e.g., within 300 μm, or are in contact in the Y-axis direction, and in between this distance Lm and a length Lc in the Y-axis direction of coils 38, a relation Lm≧Lc is valid. That is, in the Y-axis direction, the total of distance (D1), which is from an end on one side (minus Y side) of wafer stage WST to an end on one side of magnet unit 51A, and distance (D2), which is from an end on the other side (plus Y side) of measurement stage MST to an end on the other side of magnet unit 51B, is at least equal to or longer than the length of one coil 38 in the Y-axis direction. Namely, in the present embodiment, to make the relation Lm≧(D1+D2) Lc effective, or in other words, to make sure that magnet 53 structuring magnet unit 51A and magnet 53 structuring magnet unit 51B do not simultaneously face the same coil 38 structuring coil unit 60 in a state where wafer stage WST and measurement stage MST are positioned within a predetermined range (a range facing stator 60) above stage base 21, and also are in proximity by a predetermined distance (e.g., within 300 μm) or in contact with each other in the Y-axis direction, a placement of a plurality of magnets in the periphery of magnet unit 51A on wafer stage WST and a placement of a plurality of magnets in the periphery of magnet unit 51B on measurement stage MST are decided according to the size and the placement of coils 38 of coil unit 60. Incidentally, while Lm is set equal to or more than coil length Lc at least in the Y-axis direction, more preferably, Lm can be set shorter than the length of two coils so that the relation of, for example, 2Lc≧Lm≧(D1+D2)≧Lc becomes valid. Or, Lm can be shorter than one and a half of the coil, so that 1.5Lc≧Lm≧(D1+D2)≧Lc. Further, distance Lm can be set, based on the magnetic pole pitch of magnet unit 51A (or magnet unit 51B). For example, distance Lm can be set to be equal to or more than two magnetic pole pitches.

FIG. 6 shows a block diagram of an input-output relation of main controller 20 which mainly structures a control system of exposure apparatus 100 that has overall control of each part. Main controller 20 includes a so-called workstation (or a microcomputer) and the like, and has overall control of each section of exposure apparatus 100. In FIG. 6, reference sign 143 indicates a group of measuring instruments previously described, such as illuminance monitor 122, illuminance irregularity measuring instrument 104, aerial image measuring instrument, wavefront aberration measuring instrument and the like provided on measurement table MTB.

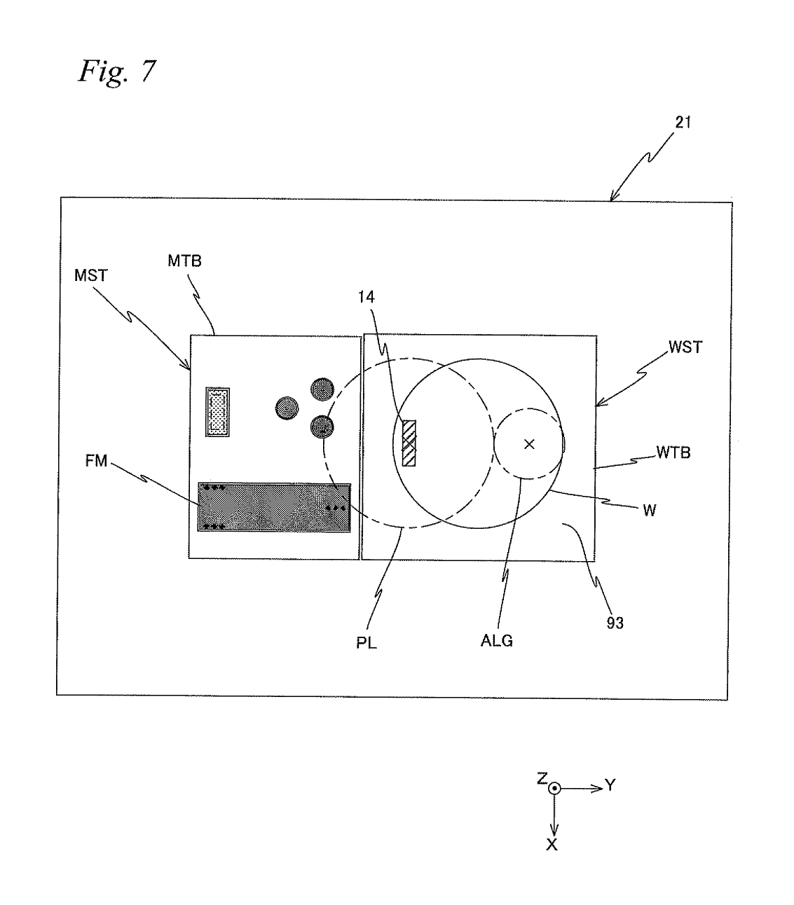

Next, a concurrent processing operation using wafer stage WST and measurement stage MST in exposure apparatus 100 related to the present embodiment will be described, based on FIG. 7 and the like. Incidentally, during the operation below, by controlling liquid immersion device 132 so that a predetermined amount of liquid Lq is supplied from liquid supply nozzle 131A and a predetermined amount of liquid Lq is recovered from liquid recovery nozzle 131B, main controller 20 continues to fill in an optical path space on the image plane side of projection optical system PL with liquid Lq.

FIG. 7 shows a state where exposure by a step-and-scan method is performed on wafer W (here, as an example, the last wafer of a lot (25 or 50 wafers per lot)) on wafer stage WST. At this point, measurement stage MST is actually waiting at a predetermined waiting position where it does not collide with wafer stage WST.

The exposure operation described above is performed by main controller 20, by repeating a movement operation between shots where wafer stage WST is moved to a scanning starting position (acceleration starting position) for exposing each shot area on wafer W and a scanning exposure operation where the pattern formed on reticle R is transferred by the scanning exposure method onto each shot area, based on results of wafer alignment and the like performed beforehand, for example, such as Enhanced Global Alignment (EGA). Incidentally, the exposure operation described above is performed in a state where liquid Lq is held in the space between tip lens 191 and wafer W.

Then, at the stage when exposure to wafer W has been completed on the wafer stage WST side, main controller 20 controls planar motor 50B of stage driving system 124 based on the measurement values of interferometer system 118, and as shown in FIG. 2, moves measurement stage MST (measurement table MTB) to a position in proximity with the −Y side of wafer stage WST which is at an exposure finishing position. At this point, of interferometer system 118, main controller 20 monitors measurement values of an interferometer which measures the position in the Y-axis direction of each table, and maintains a non-contact state by setting measurement table MTB and wafer table WTB apart in the Y-axis direction, for example, by around 300 μm. Incidentally, the arrangement is not limited to this, and main controller 20 can make the −Y side surface of measurement table MTB be in contact with the +Y side surface of wafer table WTB.

Next, main controller 20 begins an operation of simultaneously driving both stages WST and MST in the +Y direction, while maintaining the positional relation of wafer table WTB and measurement table MTB in the Y-axis direction.

When wafer stage WST and measurement stage MST are simultaneously moved in the manner described above by main controller 20, accompanying this movement of wafer stage WST and measurement stage MST in the +Y direction, liquid Lq held in the space between tip lens 191 of projection unit PU and wafer W sequentially moves from the area on wafer W to plate 93 (wafer table WTB) to measurement table MTB. That is, liquid Lq moves to a state where it is held in the space between measurement table MTB and tip lens 191.

Here, in the present embodiment, as it can be seen from FIG. 4, a part of magnets 53 structuring magnet unit 51A and a part of magnets 53 structuring magnet unit 51B are kept from simultaneously facing any of the coils 38 when liquid Lq (liquid immersion area 14) is delivered from the area on wafer table WTB to the area on measurement table MTB in the manner described above. Accordingly, in the present embodiment, main controller 20 allows the delivery of liquid Lq (liquid immersion area 14) from the area on wafer table WTB to the area on measurement table MTB to be performed, by moving wafer stage WST and measurement stage MST in the +Y direction while maintaining the proximity or the contact state with each other in the Y-axis direction, via each of the planar motors 50A and 50B. In this case, because the magnetic field generated by the same coil 38 does not act simultaneously on magnet unit 51A and magnet unit 51B, wafer stage WST and measurement stage MST can be driven in a stable manner, which keeps both stages from colliding, or keeps liquid Lq from leaking through a gap in the case the gap between both stages become partly wide.

When the delivery of liquid Lq (liquid immersion area 14) from the area on wafer table WTB to the area on measurement table MTB described above is completed, main controller 20 moves wafer stage WST to a predetermined wafer exchange position while controlling the position of wafer stage WST by planar motor 50A based on the measurement values of interferometer system 118, and also performs wafer exchange of the wafer to a first wafer of the following lot, and concurrently with this operation, executes predetermined measurements using measurement stage MST as necessary.

As a predetermined measurement described above, for example, base line measurement of alignment system ALG can be given. To be more specific, main controller 20 simultaneously detects the pair of the first fiducial marks on fiducial mark plate FM provided on measurement table MTB and the corresponding pair of reticle alignment marks on reticle R using reticle alignment detection systems RAa and RAb previously described, and detects a positional relation between the pair of the first fiducial marks and the corresponding reticle alignment marks. At this point, the first fiducial marks are detected via projection optical system PL and liquid Lq. Further, simultaneously with this, main controller 20 detects a positional relation between the detection center of alignment system ALG and the second fiducial mark, by detecting the second fiducial mark on fiducial mark plate FM described above with alignment system ALG.

Then, main controller 20 obtains a distance (or a positional relation) between the projection center of the reticle pattern and the detection center of alignment system ALG by projection optical system PL, that is, the base line of alignment system ALG, based on the positional relation between the pair of the first fiducial marks and the corresponding reticle alignment marks and the positional relation between the detection center of alignment system. ALG and the second fiducial mark described above, and a known positional relation between the pair of the first fiducial marks and the second fiducial mark.

Then, at the stage when the operations on both stages WST and MST described above have been completed, main controller 20 sets measurement stage MST and wafer stage WST to the proximity or the contact state previously described, and moves wafer stage WST (wafer) to a position below projection optical system PL by driving both stages WST and MST in the −Y direction opposite to the earlier description while holding liquid Lq below projection optical system FL and maintaining the positional relation in the Y-axis direction of wafer stage WST and measurement stage MST. Here, also on the delivery of liquid Lq (liquid immersion area 14) from the area on measurement table MTB to the area on wafer table WTB, a part of magnets 53 structuring magnet unit 51A and a part of magnets 53 structuring magnet unit 51B are kept from simultaneously facing any of the coils 38. Accordingly, in the present embodiment, main controller 20 allows the delivery of liquid Lq (liquid immersion area 14) from the area on measurement table MTB to the area on wafer table WTB, by moving wafer stage WST and measurement stage MST in the −Y direction while maintaining the proximity or the contact state with each other in the Y-axis direction, via each of the planar motors 50A and 50B. In this case as well, for the same reasons as is previously described, wafer stage WST and measurement stage MST can be driven in a stable manner, which keeps both stages from colliding, or keeps liquid Lq from leaking through a gap in the case the gap between both stages become partly wide.

When moving wafer stage WST (wafer) to the area below projection optical system PL is completed, main controller 20 withdraws measurement stage MST to a predetermined position.

Then, main controller 20 executes wafer alignment and exposure operation by the step-and-scan method to a new wafer, and sequentially transfers the reticle pattern onto the plurality of shot areas on wafer. Hereinafter, a similar operation is repeatedly performed.

As is described so far, according to exposure apparatus 100 of the present embodiment, stage device 150 is equipped with wafer stage WST and measurement stage MST which can move independently to each other above stage base 21 in directions of six degrees of freedom, and with planar motors 50A and 50B (stage driving system 124) that are provided in wafer stage WST and measurement stage MST, respectively, having magnet units 51A and 51B that each include the plurality of magnets 53 and coil unit 60 including the plurality of coils 38 arranged two-dimensionally in stage base 21 that drive wafer stage WST and measurement stage MST by a driving force generated y the electromagnetic interaction between magnet unit 51A and 51B. Further, in a state where wafer stage WST and measurement stage MST are positioned within a predetermined range above stage base 21, and also in proximity within a predetermined distance from each other or in contact in the Y-axis direction, the placement on wafer stage WST or on measurement stage MST of the plurality of magnets in the periphery of magnet units 51A and 51B is decided, according to the size and placement of coils 38 of coil unit 60 so that the magnets structuring magnet unit 51A and the magnets structuring magnet unit 515 do not simultaneously face the same coil 38 structuring coil unit 60. Accordingly, main controller 20 can drive wafer stage WST and measurement stage MST in a stable manner independently from each other within the XY plane.

Further, according to exposure apparatus 100 of the present embodiment, on the delivery of liquid Lq (liquid immersion area 14) between wafer table WTB and measurement table MTB previously described, main controller 20 can drive wafer stage WST and measurement stage MST in a stable manner independently from each other within the XY plane. To be more specific, on the delivery of liquid Lq (liquid immersion area 14) as well, main controller 20 can independently drive wafer stage WST and measurement stage MST in the Y-axis direction, while maintaining the proximity or the contact state in the Y-axis direction. Accordingly, the gap distance between wafer stage WST and measurement stage MST can be constantly maintained, which keeps both stages WST and MST from colliding, and keeps the liquid from leaking through the gap between both stages. Therefore, according to exposure apparatus 100, abnormality occurring such as collision of both stages WST and MST and leakage of the liquid, or furthermore, a decrease in productivity due to shutdown of the apparatus caused by such abnormality occurring can be effectively suppressed.

Further, in exposure apparatus 100 related to the present embodiment, by performing exposure with high resolution and also with a larger depth of focus than in air by the liquid immersion exposure, the pattern of reticle R can be transferred on the wafer with good accuracy, and for example, transfer of a fine pattern having a device rule of around 45 to 100 nm with an ArF excimer laser beam can be achieved.

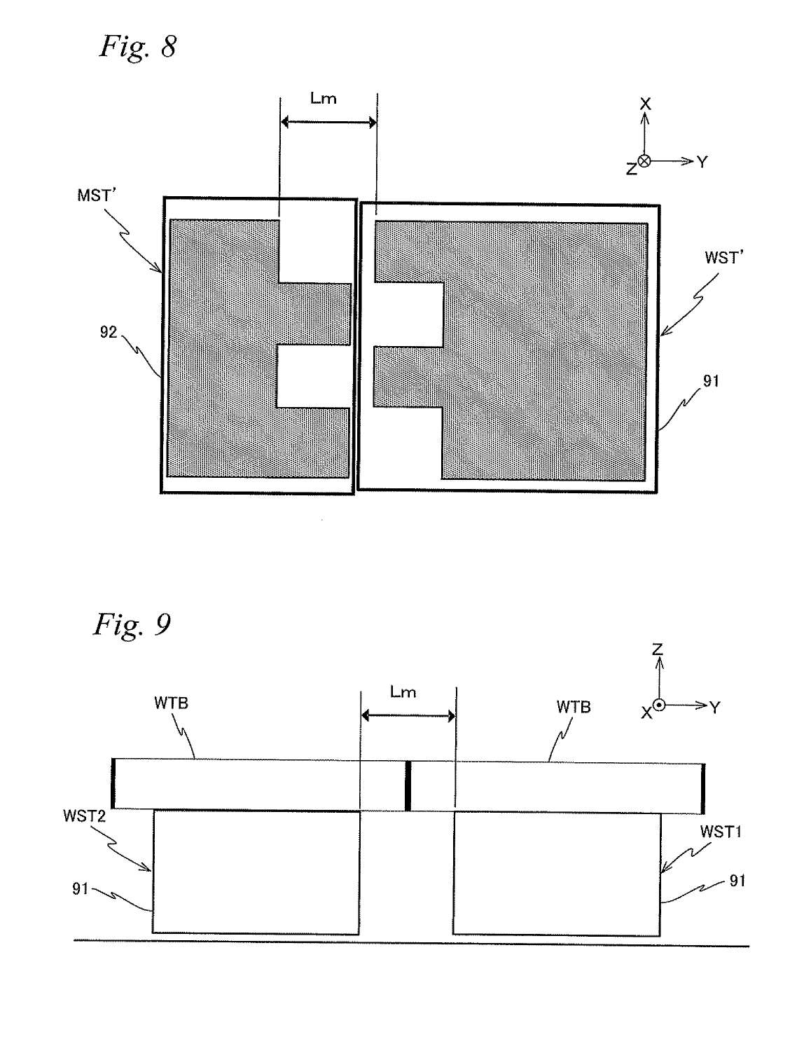

Incidentally, in the embodiment described above, the case has been described where coil unit 60 is structured using the square shaped coils 38 arranged two-dimensionally in the XY directions, and magnet units 51A and 518 consisting of a plurality of magnets placed in a square area corresponding to this are used. However, the present invention is not limited to this, and for example, as in wafer stages WST′ and MST′ whose bottom surface views are each shown in FIG. 8, a layout can be employed in which in an area where one end and the other end in the Y-axis direction of the bottom surface of wafer stage main section 91 and measurement stage main section 92 are uneven, magnets of magnet units 51A and 51B are placed. In the stage device equipped with wafer stages WST′ and MST′ related to the modified example in FIG. 8 and the liquid immersion exposure apparatus equipped with the stage device, in a positional relation shown in FIG. 8, that is, in a state where stage WST′ and measurement stage MST′ are positioned within a predetermined range above stage base 21, and are in a proximity or a contact state with each other within a predetermined distance in the Y-axis direction and also in a predetermined positional relation with each other in the X-axis direction as shown in FIG. 8, placement of the plurality of magnets in the periphery of each of the magnet units 51A and 51B on wafer stage WST′ and measurement stage MST′ is decided, according to the size and placement of coils 38 of coil unit 60 so that the magnets structuring magnet unit 51A and the magnets structuring magnet unit 51B do not simultaneously face the same coil 38 structuring coil unit 60. Accordingly, main controller 20 can independently drive wafer stage WST′ and measurement stage MST′ shown in FIG. 8, and while maintaining the positional relation of both stages, by driving wafer stage WST and measurement stage MST in the +Y direction or in the −Y direction and performing delivery of liquid Lq previously described between both stages, abnormality occurring such as collision of both stages WST and MST and leakage of the liquid, or furthermore, a decrease in productivity due to shutdown of the apparatus caused by such abnormality occurring can be effectively suppressed.

Incidentally, in the embodiment described above, while wafer stage WST and measurement stage MST are made independently drivable by keeping Y driving magnets structuring magnet unit 51A and Y driving magnets structuring magnet unit 51B from simultaneously facing the same Y-axis direction driving coil structuring coil unit 60, the present invention is not limited to this.

For example, the placement of the plurality of magnets (especially the Y driving magnets) in the periphery of each of the magnet units 51A and 51B on wafer stage WST and measurement stage MST can be decided, according to the size and placement of the coils of coil unit 60 so that an electromagnetic interaction occurs between a magnetic field generated by a predetermined coil structuring coil unit 60 and a magnet structuring magnet unit 51A while an electromagnetic interaction does not occur between the magnetic field generated by the predetermined coil and a magnet structuring magnet unit 51B. In this case, electromagnetic interaction does not occur, includes the case where the magnetic field generated by the predetermined coil does not reach the magnet structuring magnet unit 51B and no electromagnetic interaction occurs, as well as the case where an electromagnetic interaction occurs and a driving force is generated but in a state where the driving force generated is sufficiently small so that wafer stage WST and measurement stage MST can be controlled independently with each other.

Incidentally, in the embodiment described above, while the case has been described of an exposure apparatus equipped with measurement stage MST separate from wafer stage WST, the present invention is not limited to this, and the embodiment described above can also be applied to a multi-stage type exposure apparatus equipped with a plurality of wafer stages holding the wafer like the ones disclosed in, for example, U.S Patent Application Publication No. 2011/0025998, and U.S. Pat. No. 5,969,441 and the like. In this case, for example, as in the modified example shown in FIG. 9, on the upper part of wafer stage main section 91 structuring each of the two wafer stages WST1 and WST2, wafer tables WTB having a pair of protruding portions that protrude by Lm/2 or more from both side surfaces in the Y-axis direction of wafer stage main section 91 can be mounted. In this case, magnet units can be placed on the entire bottom surface of wafer stage main section 91. Furthermore, in this case, the pair of protruding portions whose length in the Y-axis direction is Lm or more can be provided only in one of the wafer tables WTB, or the pair of protruding portions whose length in the Y-axis direction is Lm or more can be provided on only one side in the Y-axis direction of both wafer tables WTB. The point is, the two wafer tables WTB should be in a state in proximity within a predetermined distance or in contact in the Y-axis direction, with the distance in the Y-axis direction in between the wafer stage main sections 91 equipped in the two wafer stages WST being Lm or more. As a matter of course, instead of providing the protruding portions, wafer stage main section 91 and wafer table WTB can have an identical shape in a planar view, and the layout of the magnet units on the bottom surface of the two wafer stage main sections 91 can be set so that the distance in the Y-axis direction between the magnet units becomes Lm or more in a state where the two wafer stages WST are in proximity within a predetermined distance or in contact in the Y-axis direction. The same can be said for the combination of wafer stage WST and measurement stage MST of the embodiment previously described.

Incidentally, in the embodiment described above, while the case has been described where a large fiducial mark plate FM that can simultaneously perform reticle alignment and base line measurement of the alignment system is provided on measurement stage, the present invention is not limited to this, and a small fiducial mark plate can be provided on wafer stage WST that requires relative movement of the fiducial mark plate with respect to projection optical system and the alignment system at the time of reticle alignment and at the time of base line measurement.

Incidentally, instead of the square shaped coils, as disclosed in, for example, U.S. Pat. No. 6,445,093 and the like, a planar motor device is also known that has rectangular shaped coils or hexagonal shaped coils placed two-dimensionally with the coils serving as X driving coils and Y driving coils, respectively, and corresponding to these coils, X driving magnets and Y driving magnets are used. The embodiment described above can also be applied to the stage device and the exposure apparatus equipped with such a planar motor device. In this case, the placement of the plurality of magnets (especially the Y driving magnets) in the periphery of each of the magnet units 51A and 51B on wafer stage WST and measurement stage MST can be decided, according to the size and placement of the coils of coil unit 60 so that not all the magnets but Y driving magnets structuring magnet unit 51A and Y driving magnets structuring magnet unit 51B do not simultaneously face the same Y-axis direction driving coil structuring coil unit 60, in a state where wafer stage WST (a first movable body) and measurement stage MST (a second movable body) are positioned within a predetermined range above stage base 21, in a state in proximity with each other within a predetermined distance or are in contact in the Y-axis direction and are also in a state at least in a predetermined positional relation in the X-axis direction.

Further, in the embodiment described above, while the case has been described where stage device 150 is equipped with a magnetic levitation type planar motor, the present invention is not limited to this, and the stage device (movable body apparatus) can be equipped with an air levitation type planar motor. In this case, a gas static bearing such as an air bearing, which supports wafer stage WST and measurement stage MST in a non-contact manner on the upper surface of stage base 21 serving as a guide surface when wafer stage WST and measurement stage MST move, is provided on each of the bottom surfaces of wafer stage WST and measurement stage MST.

Further, in the embodiment described above, while the case has been described where wafer stage WST and measurement stage MST are both a single stage that can be driven in directions of six degrees of freedom, the present invention is not limited to this, and the stages can be a so-called coarse movement stage consisting of a coarse movement stage and a fine movement stage. In this case, the placement of magnets of a magnet unit provided in the coarse movement stage only has to satisfy the conditions previously described.

Incidentally, in the embodiment described above, while one each of the liquid supply nozzle and the liquid recovery nozzle are provided, the present invention is not limited to this, and as disclosed in, for example, PCT International Publication No. 99/49504, a structure having multiple nozzles can be employed. Further, the structure disclosed in, European Patent Application Publication No. 1,598,855 and the like can be employed for liquid immersion device 132. The point is, the structure of liquid immersion device 132 can be of any form, as long as liquid can be supplied to the space between the lowermost optical member (tip lens) 191 structuring projection optical system PL and wafer W. Further, the embodiment and the modified example described above can be applied not only to a liquid immersion exposure apparatus, but also to a typical dry exposure type exposure apparatus which does not use liquid.

Incidentally, in the embodiment described above, while the case has been described where the exposure apparatus is a scanning exposure apparatus of a step-and-scan method and the like, the present invention is not limited to this, and the exposure apparatus can be a projection exposure apparatus of a step-and-repeat method, or furthermore, an exposure apparatus of a step-and-stitch method, or an exposure apparatus of a proximity method.

Incidentally, in the embodiment described above, while the case has been described where the position of wafer stage WST and measurement stage MST is measured using the interferometer system, instead of the interferometer system, or along with the interferometer system, an encoder system can be used. As the encoder system in this case, an encoder system can be employed in which a scale is provided on the wafer table or the measurement table, and facing the scale, an encoder head section is placed external to wafer table WTB or measurement table MTB, as disclosed in, for example, U.S. Patent Application Publication No. 2008/0088843 and the like, or an encoder system having a structure of a plurality of encoder head sections being provided on wafer table WTB and measurement table MTB, and facing these sections, a grating section (for example, a two-dimensional grating or a linear grating section placed two-dimensionally) is placed external to wafer table WTB and measurement table MTB, can also be employed, as disclosed in, for example, U.S. Patent Application Publication No. 2006/0227309 and the like.

Further, the projection optical system of the exposure apparatus in the embodiment described above is not limited to the reduction system, and can either be an equal magnifying or a magnifying system, and projection optical system PL is not limited to the refractive system, and can also either be a reflection system and catodioptric system, and the projection image can either be an inverted image or an upright image.

Incidentally, the light source of the exposure apparatus in the embodiment described above is not limited to the ArF excimer laser, and a pulse laser light source such as a KrF excimer laser (output wavelength 248 nm), an F₂ laser (output wavelength 157 nm), an Ar₂ laser (output wavelength 126 nm), a Kr₂ laser (output wavelength 146 nm) and the like, or a super high pressure mercury lamp which emits a g-line (wavelength 436 nm), an i-line (wavelength 365 nm) and the like can also be used. Further, a harmonic generator of a YAG laser and the like can also be used. Besides this, a harmonic wave, which is obtained by amplifying a single-wavelength laser beam in the infrared or visible range emitted by a DFB semiconductor laser or fiber laser as vacuum ultraviolet light, with a fiber amplifier doped with, for example, erbium (or both erbium and ytterbium), and by converting the wavelength into ultraviolet light using a nonlinear optical crystal, can also be used. Further, the projection optical system is not limited to the reduction system, and can either be an equal magnifying or a magnifying system.

Incidentally, in the embodiment described above, while a light transmissive type mask in which a predetermined light-shielding pattern (or a phase pattern or a light-attenuation pattern) is formed on a light transmitting substrate is used, instead of this mask, an electron mask on which a light-transmitting pattern, a reflection pattern, or an emission pattern is formed according to electronic data of the pattern that is to be exposed can also be used, as disclosed in, for example, U.S. Pat. No. 6,778,257.

Further, as disclosed in, PCT International Publication No. 2001/035168 and the like, the embodiment described above can also be applied to an exposure apparatus (lithography system) which forms a line-and-space pattern on wafer W by forming an interference fringe on wafer W.

Furthermore, as disclosed in, for example, U.S. Pat. No. 6,611,316, the embodiment described above can also be applied to an exposure apparatus that synthesizes two reticle patterns on a wafer via a projection optical system, and by performing scanning exposure once, performs double exposure of one shot area on the wafer almost simultaneously.

Incidentally, in the embodiment described above, the object (the object subject to exposure on which an energy beam is irradiated) on which the pattern is to be formed is not limited to a wafer, and may be another object such as a glass plate, a ceramic substrate, a film member, or a mask blank and the like.

The usage of the exposure apparatus is not limited to the exposure apparatus used for producing semiconductors, and for example, and can also be widely applied to an exposure apparatus for liquid crystals used to transfer a liquid crystal display device pattern on a square shaped glass plate, or an exposure apparatus used to manufacture an organic EL, a thin film magnetic head, an imaging device (such as a CCD), a micromachine, a DNA chip and the like. Further, the embodiment described above can also be applied not only to an exposure apparatus for producing microdevices such as semiconductor devices, but also to an exposure apparatus which transfers a pattern on a glass substrate or a silicon wafer, in order to manufacture a reticle or a mask used in a light exposure apparatus, an EUV exposure apparatus, an X-ray exposure apparatus, and an electron beam exposure apparatus and the like.

Incidentally, semiconductor devices are manufactured through the following steps; a step of performing function/performance design of the device, a step of manufacturing a reticle based on the design, a step of manufacturing a wafer from silicon materials, a lithography step of transferring the pattern formed on the reticle onto an object such as the wafer with the exposure apparatus in the embodiment described above by the liquid immersion exposure previously described, a device assembly step (including a dicing process, a bonding process, and a package process), an inspection step and the like. In this case, in the lithography step, because the device pattern is formed on the object by executing the liquid immersion exposure method previously described using the exposure apparatus of the embodiment described above, highly integrated devices can be produced with good yield.

Incidentally, the disclosures of the PCT International Publications, the U.S. patent application Publications and the U.S. patents that are cited in the description so far related to exposure apparatuses and the like are each incorporated herein by reference.

While the above-described embodiment of the present invention is the presently preferred embodiment thereof, those skilled in the art of lithography systems will readily recognize that numerous additions, modifications, and substitutions may be made to the above-described embodiment without departing from the spirit and scope thereof. It is intended that all such additions, modifications, and substitutions fall within the scope of the present invention, which is best defined by the claims appended below.

What is claimed is:

1. A movable body apparatus, comprising:
a first movable body which can move along a two-dimensional plane above a stage base;
a second movable body which can move along the two-dimensional plane independently from the first movable body above the stage base; and
a planar motor which has a first magnet unit including a plurality of magnets provided in the first movable body, a second magnet unit including a plurality of magnets provided in the second movable body, and a coil unit including a plurality of coils arranged two-dimensionally above the stage base, and drives the first movable body by a driving force generated by an electromagnetic interaction between the first magnet unit and the coil unit and drives the second movable body by a driving force generated by an electromagnetic interaction between the second magnet unit and the coil unit, wherein
a placement of the plurality of magnets in the periphery of each of the first magnet unit and the second magnet unit on the first movable body or the second movable body is decided according to a size and a placement of coils of the coil unit, so that no magnets structuring the first magnet unit and no magnets structuring the second magnet unit simultaneously face the same first direction driving coil structuring the coil unit, in a state where the first movable body and the second movable body are in a first state of being positioned within a predetermined range above the stage base and in proximity within a predetermined distance or in contact with each other in a first direction parallel to the two-dimensional plane, and also in a state where the first movable body and the second movable body are at least in a predetermined positional relation in a second direction orthogonal to the first direction within the two-dimensional plane.

2. The movable body apparatus according to claim 1 wherein
a placement of the plurality of magnets in the periphery of each of the first magnet unit and the second magnet unit on the first movable body or the second movable body is decided according to a size and a placement of coils of the coil unit, so that no magnets structuring the first magnet unit and no magnets structuring the second magnet unit simultaneously face the same first direction driving coil structuring the coil unit, regardless of a positional relation in the second direction between the first movable body and the second movable body when the first movable body and the second movable body are in the first state.

3. An exposure apparatus which exposes an object with an energy beam via an optical system and liquid, the apparatus comprising:
a movable body apparatus according to claim 1 wherein the object is mounted on the first movable body or the second movable body, or on the first movable body and the second movable body; and
a liquid immersion device which supplies liquid to an area directly below the optical system and forms a liquid immersion area between the optical system and the first movable body or the second movable body, or the optical system and the first movable body and the second movable body, wherein
delivery of the liquid immersion area is performed between the first movable body and the second movable body when the first movable body and the second movable body are in the first state.

4. The exposure apparatus according to claim 3 wherein
the first movable body is an object stage on which the object is mounted, and
the second movable body is a measurement stage on which a measurement member is provided.

5. The exposure apparatus according to claim 4 wherein
in the object stage, the first magnet unit is placed substantially on an entire surface which is a surface on a side facing the stage base, and
in the measurement stage, the second magnet unit is placed in an area of a surface on a side facing the stage base, the area excluding a portion on one end in the first direction which is on a side that can be in proximity with the object stage.

6. The exposure apparatus according to claim 3 wherein
the first movable body and the second movable body are both an object stage on which the object is mounted.

7. The exposure apparatus according to claim 6 wherein
in the first movable body and the second movable body, a protruding portion which protrudes outwardly at least to one side in the first direction is provided in each of the upper end portions of the first movable body and the second movable body, and
a protruding dimension of the protruding portion in the first direction is decided according to a dimension of the first direction driving coil in the first direction.

8. The exposure apparatus according to claim 3 wherein
exposure of the object is performed by scanning the object mounted on the first movable body or the second movable body in the first direction with respect to the energy beam via the optical system.

9. A device manufacturing method, including:
exposing a sensitive object using the exposure apparatus according to claim 3; and
developing the object which has been exposed.

10. A movable body apparatus, comprising:
a first movable body which can move along a two-dimensional plane above a stage base;
a second movable body which can move along the two-dimensional plane independently from the first movable body above the stage base; and
a planar motor which has a first magnet unit including a plurality of magnets provided in the first movable body, a second magnet unit including a plurality of magnets provided in the second movable body, and a coil unit including a plurality of coils arranged two-dimensionally above the stage base, and drives the first movable body by a driving force generated by an electromagnetic interaction between the first magnet unit and the coil unit and the second movable body by a driving force generated by an electromagnetic interaction between the second magnet unit and the coil unit, wherein
a placement of the plurality of magnets in the periphery of each of the first magnet unit and the second magnet unit on the first movable body or the second movable body is decided according to a size and a placement of coils of the coil unit, so that an electromagnetic interaction occurs between a magnetic field generated by a predetermined coil structuring the coil unit and magnets structuring the first magnet unit, and an electromagnetic interaction does not occur between the magnetic field generated by the predetermined coil and magnets structuring the second magnet unit, in a state where the first movable body and the second movable body are in a first state of being positioned within a predetermined range above the stage base and in proximity within a predetermined distance or in contact with each other in a first direction parallel to the two-dimensional plane, and also in a state where the first movable body and the second movable body are at least in a predetermined positional relation in a second direction orthogonal to the first direction within the two-dimensional plane.

11. An exposure apparatus which exposes an object with an energy beam via an optical system and liquid, the apparatus comprising:
a movable body apparatus according to claim 10 wherein the object is mounted on the first movable body or the second movable body, or on the first movable body and the second movable body; and
a liquid immersion device which supplies liquid to an area directly below the optical system and forms a liquid immersion area between the optical system and the first movable body or the second movable body, or the optical system and the first movable body and the second movable body, wherein
delivery of the liquid immersion area is performed between the first movable body and the second movable body when the first movable body and the second movable body are in the first state.

12. The exposure apparatus according to claim 11 wherein
the first movable body is an object stage on which the object is mounted, and
the second movable body is a measurement stage on which a measurement member is provided.

13. The exposure apparatus according to claim 12 wherein
in the object stage, the first magnet unit is placed substantially on an entire surface which is a surface on a side facing the stage base, and
in the measurement stage, the second magnet unit is placed in an area of a surface on a side facing the stage base, the area excluding a portion on one end in the first direction which is on a side that can be in proximity with the object stage.

14. The exposure apparatus according to claim 11 wherein
the first movable body and the second movable body are both an object stage on which the object is mounted.

15. The exposure apparatus according to claim 14 wherein
in the first movable body and the second movable body, a protruding portion which protrudes outwardly at least to one side in the first direction is provided in each of the upper end portions of the first movable body and the second movable body, and
a protruding dimension of the protruding portion in the first direction is decided according to a dimension of the first direction driving coil in the first direction.

16. The exposure apparatus according to claim 11 wherein
exposure of the object is performed by scanning the object mounted on the first movable body or the second movable body in the first direction with respect to the energy beam via the optical system.

17. A device manufacturing method, including:
exposing a sensitive object using the exposure apparatus according to claim 11; and
developing the object which has been exposed.

18. A movable body apparatus, comprising:
a first movable body which can move along a two-dimensional plane above a stage base;
a second movable body which can move along the two-dimensional plane independently from the first movable body above the stage base; and
a planar motor which has a first magnet unit including a plurality of magnets provided in the first movable body, a second magnet unit including a plurality of magnets provided in the second movable body, and a coil unit including a plurality of coils arranged two-dimensionally above the stage base, and drives the first movable body by a driving force generated by an electromagnetic interaction between the first magnet unit and the coil unit and the second movable body by a driving force generated by an electromagnetic interaction between the second magnet unit and the coil unit, wherein
a total of a distance from an end on one side of the first movable body to an end on one side of the first magnet unit and a distance from the end on the other side of the second movable body to an end on the other side of the second magnet unit, in a first direction parallel to the two-dimensional plane, includes a length which is at least one coil length in the first direction.

19. The movable body apparatus according to claim 18 wherein
when a distance from the end on one side of the first movable body to the end of one side of the first magnet unit in the first axis direction is expressed as D1, a distance from the end on the other side of the second movable body to the end on the other side of the second magnet unit in the first axis direction is expressed as D2, and a length of the one coil in the first direction is expressed as Lc, a relation (D1+D2)≧Lc is defined, in a state where the first movable body and the second movable body are positioned within a predetermined range above the stage base, in a first state where the end on the one side of the first movable body and the end on the other side of the second movable body are in proximity within a predetermined distance or in contact with each other in the first direction and at least in a predetermined positional relation in a second direction orthogonal to the first direction within the two-dimensional plane.

20. The movable body apparatus according to claim 18 wherein
when a spacing between the first magnet unit and the second magnet unit in the first direction is expressed as Lm, and a length of the one coil in the first direction is expressed as Lc, a relation Lm≧Lc is defined, in a state where the first movable body and the second movable body are positioned within a predetermined range above the stage base, in a first state where the end on the one side of the first movable body and the end on the other side of the second movable body are in proximity within a predetermined distance or in contact with each other in the first direction and at least in a predetermined positional relation in a second direction orthogonal to the first direction within the two-dimensional plane.

21. An exposure apparatus which exposes an object with an energy beam via an optical system and liquid, the apparatus comprising:
the movable body apparatus according to claim 18 on which the object is mounted on the first movable body or the second movable body, or on the first movable body and the second movable body; and
a liquid immersion device which supplies liquid in a space directly below the optical system and forms a liquid immersion area between the optical system and the first movable body or the second movable body or the first movable body and the second movable body, wherein
delivery of the liquid immersion area is performed between the first movable body and the second movable body in a state where the first movable body and the second movable body are in the first state.

22. The exposure apparatus according to claim 21 wherein
the first movable body is an object stage on which the object is mounted, and
the second movable body is a measurement stage on which a measurement member is provided.

23. The exposure apparatus according to claim 22 wherein
in the object stage, the first magnet unit is placed substantially on an entire surface which is a surface on a side facing the stage base, and
in the measurement stage, the second magnet unit is placed in an area of a surface on a side facing the stage base, the area excluding a portion on one end in the first direction which is on a side that can be in proximity with the object stage.

24. The exposure apparatus according to claim 21 wherein
the first movable body and the second movable body are both an object stage on which the object is mounted.

25. The exposure apparatus according to claim 24 wherein
in the first movable body and the second movable body, a protruding portion which protrudes outwardly at least to one side in the first direction is provided in each of the upper end portions of the first movable body and the second movable body, and
a protruding dimension of the protruding portion in the first direction is decided according to a dimension of the first direction driving coil in the first direction.

26. The exposure apparatus according to claim 21 wherein
exposure of the object is performed by scanning the object mounted on the first movable body or the second movable body in the first direction with respect to the energy beam via the optical system.

27. A device manufacturing method, including:
exposing a sensitive object using the exposure apparatus according to claim 21; and
developing the object which has been exposed.
